(19) United States
(12) Patent Application Publication
(10) Pub. No.: US 2022/0136919 A1
(43) Pub. Date: May 5, 2022

(54) SPIKE SPECTRUM OUTPUT-TYPE PRESSURE SENSOR COMPRISING ELECTROLYTE, AND METHOD FOR MANUFACTURING SAME

(71) Applicant: POSTECH RESEARCH AND BUSINESS DEVELOPMENT FOUNDATION, Pohang-si (KR)

(72) Inventors: Unyong JEONG, Pohang-si (KR); Tae Yeong KIM, Pohang-si (KR)

(21) Appl. No.: 17/434,100

(22) PCT Filed: Apr. 8, 2020
(86) PCT No.: PCT/KR2020/004718

§ 371 Date: Aug. 26, 2021

(30) Foreign Application Priority Data
May 8, 2019 (KR) 10-2019-0053737

(51) Int. Cl. G01L 9/18; C09D 4/00; G01L 9/00

(52) U.S. Cl. CPC G01L 9/18; G03F 7/2002; G01L 9/0091; C09D 4/00

(57) ABSTRACT

Disclosed is a spike spectrum output-type pressure sensor including an electrolyte and a method of manufacturing the same. The pressure includes a first electrode, a pressure sensing unit positioned on the first electrode and including a pattern including an electrolyte, a spacer positioned on the first electrode and configured to partially or fully surround the pressure sensing unit, and a second electrode positioned on the spacer and on the pressure sensing unit and spaced apart from the pressure sensing unit. The pressure sensor of the present invention can provide reliable pressure sensing results even in an environment where noise may occur due to stable signal transmission of a spike spectrum, which is a kind of frequency-based signal.

### TECHNICAL FIELD

The present invention relates to a spike spectrum output-type pressure sensor including an electrolyte and a manufacturing method thereof. More particularly, the present invention relates to a pressure sensor for outputting a spike spectrum by including a pressure sensing unit having a pattern including an electrolyte, and a method for manufacturing the same.

### BACKGROUND ART

Currently, pressure sensors are being used in various fields from electronic devices to robotics to biotechnology. Since conventional analog signal-based pressure sensors are affected by the contact resistance on a connector and the external parasitic resistance, there is a difficulty in that there must be a process of continuously calibrating the signal size that changes according to the connection environment. In specific applications such as robotics or bioengineering which requires a flexible pressure sensor, there is a problem in that the connection resistance is continuously changed according to the mechanical deformation of the sensor and the change in the connection resistance affects the measurement result of the sensor.

In the case of a frequency signal, it is possible to create a robust signal resistant against external factors such as the connection environment by obtaining the pressure from the signal frequency. There is a method of converting an analog signal by adding a ring oscillator to implement a frequency-based output signal, but the method has a problem of requiring an additional process.

Therefore, there is a need for research on a pressure sensor using a frequency-based signal and a method for manufacturing the same.

### DISCLOSURE

### Technical Problem

An objective of the present invention is to provide a pressure sensor using a frequency-based signal and a method for manufacturing the same to solve the problem described above.

Another objective of the present invention is to provide a pressure sensor capable of providing reliable pressure sensing results in an environment in which noise may occur, and a method for manufacturing the same.

### Technical Solution

According to one aspect of the present invention, there is provided a pressure sensor including: a first electrode; a pressure sensing unit positioned on the first electrode and having a pattern including an electrolyte; a spacer positioned on the first electrode and configured to partially or entirely surround the pressure sensing unit; and a second electrode positioned on the spacer and on the pressure sensing unit and spaced apart from the pressure sensing unit.

In addition, the pressure sensor may further include a stretchable substrate on the second electrode.

In addition, the pattern may include a plurality of domains, the domains may include the electrolyte, and each of the domains may be spaced apart from a neighboring domain.

In addition, the domain may have one or more shapes selected from the group consisting of linear, circular, elliptical, arc-shaped, sector-shaped, and polygonal shapes, and combinations thereof.

In addition, the shape of the domain may be the same as that of a neighboring domain.

Also, the domains may be spaced apart from neighboring domains at the same interval.

In addition, the electrolyte may include a photocurable polymer and a liquid electrolyte.

In addition, the photocurable polymer may include at least one selected from the group consisting of a diacrylate-based polymer and a dimethacrylate-based polymer.

In addition, the photocurable polymer may include poly(ethylene glycol) diacrylate (PEGDA).

In addition, the liquid electrolyte may include an ionic liquid.

In addition, the ionic liquid may include at least one selected from the group consisting of an aliphatic ionic liquid, an imidazolium-based ionic liquid, and a pyridinium-based ionic liquid.

In addition, the ionic liquid may include an imidazolium-based ionic liquid.

In addition, the imidazolium-based ionic liquid may include 1-butyl-3-methylimidazolium tetrafluoroborate (BMI-BF₄).

In addition, the electrolyte may further include a photoinitiator.

In addition, the first electrode or the second electrode may include at least one selected from the group consisting of gold, silver, copper, platinum, palladium, nickel, indium, aluminum, iron, rhodium, ruthenium, osmium, cobalt, molybdenum, zinc, vanadium, tungsten, titanium, manganese, chromium, silver nanowire, carbon nanotubes (CNT), and gold nanosheets.

In addition, the second electrode may include a buckled structure.

In addition, the buckle structure may include a curved surface of the second electrode.

In addition, the second electrode may have a cross-sectional surface perpendicular to a principal surface thereof, the cross-sectional surface having a zigzag shape including crests and valleys.

In addition, the stretchable substrate may include at least one selected from the group consisting of a styrene-butadiene-styrene (SBS) block copolymer, a styrene-ethylene-butylene-styrene (SEBS) block copolymer, a styrene-isoprene-styrene (SIS) block copolymer, a polyurethane (PU), polyisoprene rubber (IR), butadiene rubber (BR), ethylene-propylene-diene monomer (EPDM) rubber, polydimethylsiloxane (PDMS), silicone-based rubber, ecoflex, and dragon skin.

According to another aspect of the present invention, there is provided a method of manufacturing a pressure sensor, the method including: (a) preparing a lower plate including a first electrode and a pressure sensing unit positioned on the first electrode and having a pattern including an electrolyte; (b) preparing an upper plate including a stretchable substrate and a second electrode positioned on the stretchable substrate; and (c) forming a spacer between the first electrode of the lower plate and the second electrode of the upper plate, the space being spaced apart from the pressure sensing unit and partially or entirely surround the pressure sensing unit.

In addition, the step (a) includes the steps of: (a-1) preparing a mixture comprising a photocurable polymer precursor and a liquid electrolyte; (a-2) applying the mixture on the first electrode to prepare a first electrode/coating layer; (a-3) stacking a mask on the first electrode/coating layer to cover an upper surface of the first electrode/coating layer except for a portion to be patterned; (a-4) causing a structure resulting from the step (a-3) to be exposed to UV radiation; and (a-5) removing the mask to prepare the lower plate, in which the photocurable polymer precursor may include at least one selected from the group consisting of photocurable monomers and photocurable oligomers.

In addition, the step (b) includes the steps of: (b-1) pulling the stretchable substrate in each of the biaxial directions and fixing the stretchable substrate; (b-2) depositing a metal on the fixed stretchable substrate to form a metal layer on the stretchable substrate; and (b-3) releasing the fixed stretchable substrate to prepare the upper plate including the metal layer including a buckle structure formed on a surface thereof.

### Advantageous Effects

The pressure sensor of the present invention can provide reliable pressure sensing results even in an environment where noise may occur due to stable signal transmission of a spike spectrum, which is a kind of frequency-based signal.

### BRIEF DESCRIPTION OF DRAWINGS

Since the accompanying drawings are for reference in describing exemplary embodiments of the present invention, the technical spirit of the present invention should not be construed as being limited to the accompanying drawings.

FIG. 1 is a schematic diagram illustrating a pressure sensor according to an embodiment of the present invention.

FIG. 2 illustrates a sequence of steps for preparing a lower plate, according to one embodiment of the present invention.

FIG. 3 illustrates a sequence of steps for preparing an upper plate, according to an embodiment of the present invention.

FIG. 4 is a diagram illustrating an overall contact area that discretely increases with increasing pressure applied to a pressure sensor according to one embodiment of the present invention.

FIG. 5 illustrates a principle of generating a spike-type signal according to a pressure applied to a pressure sensor according to one embodiment of the present invention.

FIG. 6 is a schematic diagram illustrating generation of a spike-type signal according to a pressure applied to a pressure sensor according to one embodiment of the present invention.

FIG. 7 is an optical microscope image illustrating an upper plate prepared according to Preparation Example 1.

FIG. 8 includes an optical microscope image and an actual image of electrolyte patterns formed in a pressure sensor manufactured according to Example 1.

FIG. 9 illustrates spike spectrum signals according to a pressure applied to the pressure sensor manufactured according to Example 1.

FIG. 10 collectively shows the number of spikes of a spike spectrum according to a pressure applied to the pressure sensor manufactured according to Example 1.

FIG. 11 illustrates spike spectrum signals when the same pressure is repeatedly applied to the pressure sensor manufactured according to Example 1.

### BEST MODE

Herein after, examples of the present invention will be described in detail with reference to the accompanying drawings in such a manner that the ordinarily skilled in the art can easily implement the present invention.

The description given below is not intended to limit the present invention to specific embodiments. In relation to describing the present invention, when the detailed description of the relevant known technology is determined to unnecessarily obscure the gist of the present invention, the detailed description may be omitted.

The terminology used herein is for the purpose of describing particular embodiments only and is not intended to limit the scope of the present invention. As used herein, the singular forms “a”, “an”, and “the” are intended to include the plural forms as well unless the context clearly indicates otherwise. It will be further understood that the terms “comprise” or “have” when used in this specification specify the presence of stated features, integers, steps, operations, elements and/or combinations thereof, but do not preclude the presence or addition of one or more other features, integers, steps, operations, elements, and/or combinations thereof.

Terms including ordinal numbers used in the specification, “first”, “second”, etc. can be used to discriminate one component from another component, but the order or priority of the components is not limited by the terms unless specifically stated. These terms are used only for the purpose of distinguishing a component from another component. For example, a first component may be referred as a second component, and the second component may be also referred to as the first component.

In addition, when it is mentioned that a component is “formed” or “stacked” on another component, it should be understood such that one component may be directly attached to or directly stacked on the front surface or one surface of the other component, or an additional component may be disposed between them.

Hereinafter, a spike spectrum output-type pressure sensor including an electrolyte, according to the present invention, and a method of manufacturing the same will be described in detail. However, those are described as examples, and the present invention is not limited thereto and is only defined by the scope of the appended claims.

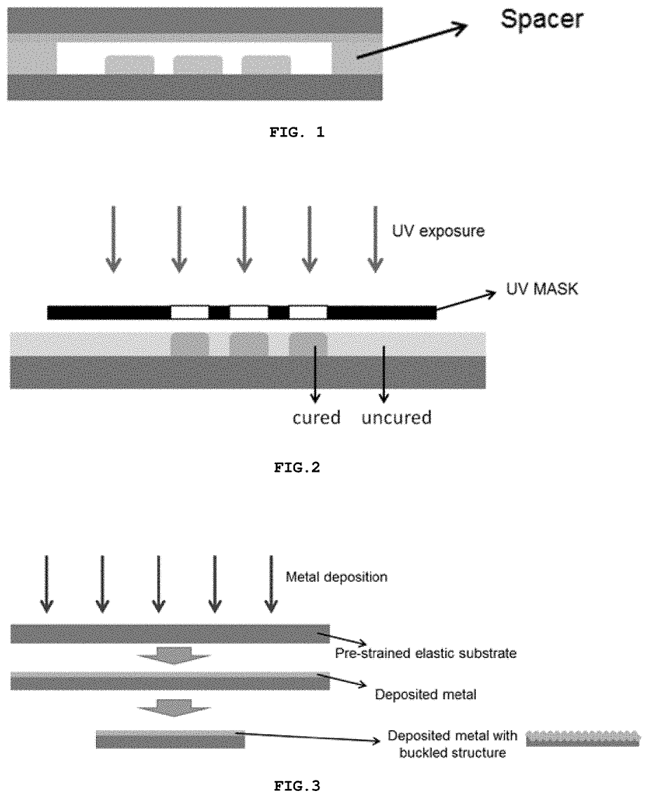

FIG. 1 is a schematic diagram illustrating a pressure sensor according to an embodiment of the present invention.

Referring to FIG. 1, the present invention provides a pressure sensor including: a first electrode; a pressure sensing unit positioned on the first electrode and having a pattern including an electrolyte; a spacer positioned on the first electrode and configured to partially or entirely surround the pressure sensing unit; and a second electrode positioned on the spacer and on the pressure sensing unit and spaced apart from the pressure sensing unit.

In addition, the pressure sensor may further include a stretchable substrate on the second electrode. The stretchable substrate includes at least one selected from the group consisting of a styrene-butadiene-styrene (SBS) block copolymer, a styrene-ethylene-butylene-styrene (SEBS) block copolymer, a styrene-isoprene-styrene (SIS) block copolymer, a polyurethane (PU), polyisoprene rubber (IR), butadiene rubber (BR), ethylene-propylene-diene monomer (EPDM) rubber, polydimethylsiloxane (PDMS), silicone-based rubber, ecoflex, and dragon skin. Preferably, the stretchable substrate includes at least one selected from the group consisting of a styrene-isoprene-styrene (SIS) block copolymer, polydimethylsiloxane (PDMS), and silicone-based rubber. More preferably, the stretchable substrate includes at least one selected from the group consisting of a styrene-isoprene-styrene (SIS) block copolymer and polydimethylsiloxane (PDMS).

In addition, the pattern may include a plurality of domains, the domains may include the electrolyte, and each of the domains may be spaced apart from neighboring domains.

In addition, the domains may have one or more shapes selected from the group consisting of linear, circular, elliptical, arc-shaped, sector-shaped, and polygonal shapes and combinations thereof.

Of the domains, the shape of one domain may be the same as that of the neighboring domains, and the size of one domain may be the same as the size of the neighboring domains. The domains may be arranged at regular intervals.

In addition, the electrolyte may include a photocurable polymer and a liquid electrolyte. The photocurable polymer is in a liquid state at room temperature and must be miscible with a liquid electrolyte. The liquid electrolyte has a high vapor pressure so as to be stable even at high temperatures such as 100° C. or higher.

In addition, the photocurable polymer may include at least one selected from the group consisting of a diacrylate-based polymer and a dimethacrylate-based polymer. Preferably, the photocurable polymer may include at least one selected from the group consisting of poly(ethylene glycol) diacrylate (PEGDA), poly(propylene glycol) diacrylate (PPGDA), poly(ethylene glycol)-block-poly(propylene glycol)-block-poly(ethylene glycol) diacrylate (PEG-PPG-PEG), poly(ethylene glycol) dimethacrylate (PEGDMA), and poly (propylene glycol) dimethacrylate (PPGDMA). More preferably, the photocurable polymer may include poly(ethylene glycol) diacrylate (GEGDA).

In addition, the liquid electrolyte may include an ionic liquid.

In addition, the ionic liquid may include at least one selected from the group consisting of an aliphatic ionic liquid, an imidazolium-based ionic liquid, and a pyridinium-based ionic liquid.

The aliphatic ionic liquid may be at least one selected from the group consisting of N,N,N-trimethyl-N-propylammonium bis(trifluoromethanesulfonyl)imide (TMPA-TFSI), N-methyl-N-propyl piperidinium bis(trifluoro Romethanesulfonyl)imide, N,N-diethyl-N-methyl-N-(2-methoxyethyl)ammoniumbis(trifluoromethanesulfonyl)imide, and N,N-diethyl-N-methyl-N-(2-methoxyethyl)ammonium tetrafluoroborate.

The imidazolium-based ionic liquid may be at least one selected from the group consisting of 1-ethyl-3-methylimidazolium bromide, 1-ethyl-3-methyl-imidazolium chloride, 1-ethyl-3-methylimidazolium (L)-lactate, 1-ethyl-3-methylimidazolium hexafluoro phosphate, 1-ethyl-3-methylimidazolium tetrafluoroborate (EMI-BF₄), 1-butyl-3-methylimidazolium chloride, 1-butyl-3-methylimidazolium hexafluorophosphate, 1-butyl-3-methylimidazolium tetrafluoroborate (BMI-BF₄), 1-butyl-3-methylimidazolium trifluoromethanesulfonate; 1-Butyl-3-methylimidazolium (L)-lactate, 1-hexyl-3-methylimidazolium bromide, 1-hexyl-3-methylimidazolium chloride, 1-hexyl-3-methylimidazolium hexafluorophosphate, 1-hexyl-3-methylimidazolium tetrafluoroborate, 1-hexyl-3-methylimidazolium trifluoromethane sulfonate, 1-octyl-3-methylimidazolium chloride, 1-octyl-3-methylimidazolium hexafluoro phosphate, 1-disyl-3-methylimidazolium chloride, 1-dodecyl-3-methylimidazolium chloride, 1-tetradisyl-3-methylimidazolium Chloride, 1-hexadecyl-3-methylimidazolium chloride, 1-octadecyl-3-methylimidazolium chloride, 1-ethyl-2,3-dimethylimidazolium bromide, 1-ethyl-2,3-dimethylimidazolium chloride, 1-butyl-2,3-dimethylimidazolium bromide, 1-butyl-2,3-dimethylimidazolium chloride, 1-butyl-2,3-dimethylimidazolium tetrafluoroborate 1-Butyl-2,3-dimethylimidazolium trifluoromethane sulfonate, 1-hexyl-2,3-dimethylimidazolium bromide, 1-hexyl-2,3-dimethylimidazolium chloride, and hexyl-2,3-dimethylimidazolium trifluoromethane sulfonate.

The pyridinium-based ionic liquid may be at least one selected from the group consisting of 1-ethyl pyridinium bromide, 1-ethyl pyridinium chloride, 1-butyl pyridinium bromide, 1-butyl pyridinium chloride, 1-butyl pyridinium hexafluorophosphate, 1-butyl pyridinium tetrafluoroborate, 1-butyl pyridinium trifluoromethane sulfonate, 1-hexyl pyridinium bromide, 1-hexyl pyridinium chloride, 1-hexyl pyridinium hexafluoro phosphate, 1-hexyl pyridinium tetrafluoro borate, and 1-hexyl pyridinium trifluoromethane sulfonate.

The ionic liquid may be preferably an imidazolium-based ionic liquid, and the imidazolium-based ionic liquid may be preferably 1-butyl-3-methylimidazolium tetrafluoroborate (BMI-BF₄).

In addition, the electrolyte may further include a photoinitiator, and 2-hydroxy-2-methylpropiophenone may be used as the photoinitiator.

In addition, the first electrode or the second electrode may include at least one selected from the group consisting of gold, silver, copper, platinum, palladium, nickel, indium, aluminum, iron, rhodium, ruthenium, osmium, cobalt, molybdenum, zinc, vanadium, tungsten, titanium, manganese, chromium, silver nanowire, carbon nanotube (CNT), and gold nanosheet. Preferably, the first electrode or the second electrode may include at least one selected from the group consisting of aluminum and gold.

In addition, the second electrode may include a buckle structure, and the buckle structure may include a curved surface of the second electrode. Regarding the second electrode, a cross-sectional surface that is perpendicular to the principal surface of the second electrode has a zigzag shape including crests and valleys.

The present invention provides a method of manufacturing a pressure sensor, the method including the steps of: (a) preparing a lower plate including a first electrode and a pressure sensing unit positioned on the first electrode and having a pattern including an electrolyte; (b) preparing an upper plate including a stretchable substrate and a second electrode positioned on the stretchable substrate; and (c) forming a spacer between the first electrode of the lower plate and the second electrode of the upper plate, the space being spaced apart from the pressure sensing unit and partially or entirely surround the pressure sensing unit.

FIG. 2 illustrates a sequence of steps for preparing the lower plate, according to one embodiment of the present invention. Referring to FIG. 2, the step (a) includes the steps of: (a-1) preparing a mixture comprising a photocurable polymer precursor and a liquid electrolyte; (a-2) applying the mixture on the first electrode to prepare a first electrode/coating layer; (a-3) stacking a mask on the first electrode/coating layer to cover an upper surface of the first electrode/coating layer except for a portion to be patterned; (a-4) causing a structure resulting from the step (a-3) to be exposed to UV radiation; and (a-5) removing the mask to prepare the lower plate, in which the photocurable polymer precursor may include at least one selected from the group consisting of photocurable monomers and photocurable oligomers.

FIG. 3 illustrates a sequence of steps for preparing the upper plate, according to an embodiment of the present invention. Referring to FIG. 3, the step (b) includes the steps of: (b-1) pulling the stretchable substrate in each of the biaxial directions and fixing the stretchable substrate; (b-2) depositing a metal on the fixed stretchable substrate to form a metal layer on the stretchable substrate; and (b-3) releasing the fixed stretchable substrate to prepare the upper plate including the metal layer including a buckle structure formed on a surface thereof.

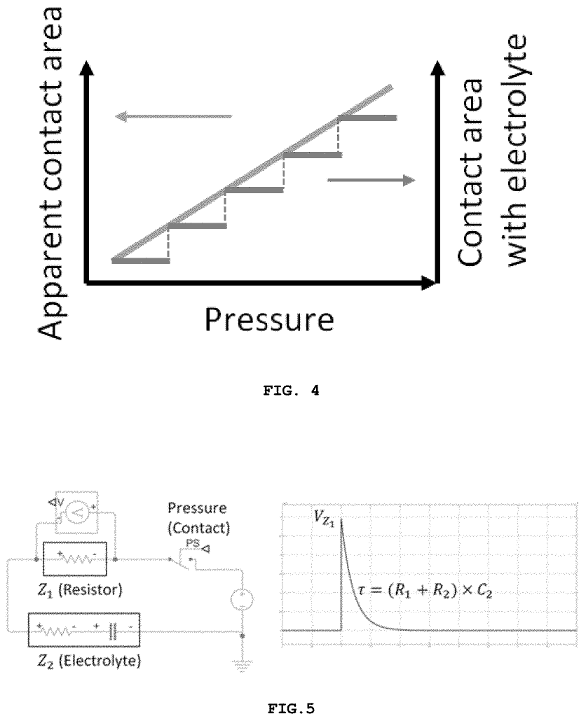

FIG. 4 is a diagram illustrating an increase in an overall contact area that discretely increases with increasing pressure applied to the pressure sensor according to one embodiment of the present invention. Referring to FIG. 4, when a strong pressing force is applied to the pressure sensor of the present invention, the area of the contact between the first electrode and the second electrode through the electrolyte increases. In this case, the electrolyte is not continuous but is patterned to be discrete, the overall contact area discretely increases.

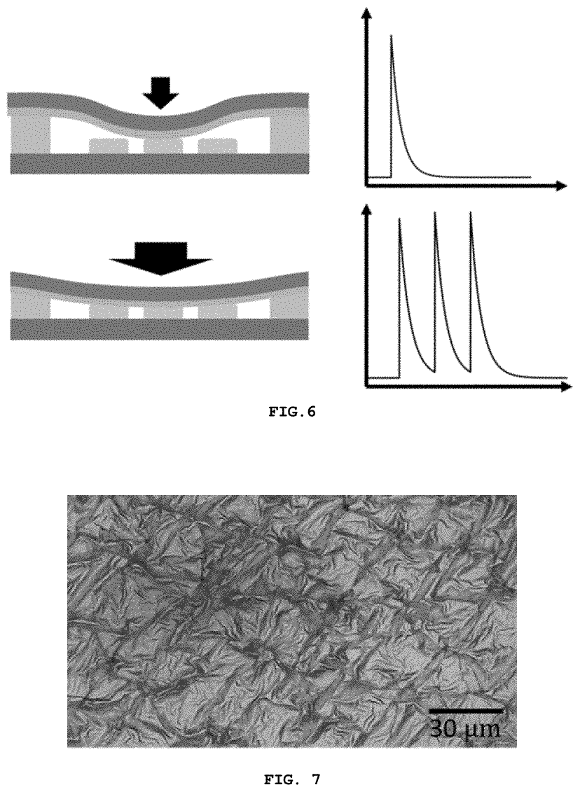

FIG. 5 illustrates a principle of generating a spike spectrum signal according to a pressure applied to the pressure sensor according to one embodiment of the present invention. Referring to FIG. 5, when a pressing force is applied to the pressure sensor of the present invention, the first electrode and the second electrode come into contact with each other through the electrolyte so that an R-C series circuit is formed. At this point, when the electrolyte is charged with electric carriers, the voltage measured at the terminal of the resistor appears in the form of a spike.

FIG. 6 is a schematic diagram illustrating generation of a spike spectrum signal according to a pressure applied to the pressure sensor according to one embodiment of the present invention. Referring to FIG. 6, in the pressure sensor of the present invention, when a contact is made through one electrolyte pattern, a voltage is measured, and the voltage gradually decreases until the next contact. Therefore, a spike-shaped signal is detected. When the applied pressure is increased, the overall area of the contacts with the discretely distributed electrolyte patterns increases. As a stronger pressure is applied, the contact is made over a larger area, and the number of spikes is increased.

### MODE FOR CARRYING OUT THE INVENTION

### EXAMPLE

Hereinafter, a preferred example of the present invention will be described. However, the example is for illustrative purposes, and the scope of the present invention is not limited thereto.

### Preparation Example 1

### Preparation of Upper Plate

Polydimethylsiloxane (PDMS), which is a main agent (SYLGARD 184 silicone elastomer base), and a curing agent (SYLGARD 184 silicone elastomer curing agent) were mixed in a mixing ratio of 10:1 (w/w), and the mixture was spin-coated to form a film having a thickness of 100 μm. The film was cured at 80° C. for 3 hours, and subsequently a mixture of a styrene-isoprene-styrene (SIS) copolymer and chloroform which were mixed in a ratio of 1:9 (w/w) were spin-coated on the film. Heat treatment was performed at 80° C. for 30 minutes to remove the residual solvent to prepare a PDMS/SIS stretchable substrate. After the PDMS/SIS stretchable substrate was biaxially pulled and fixed, gold was sputtered thereon. Thereafter, the fixation of the stretchable substrate is released. Thus, a buckle structure was formed on the surface of the gold deposited on the stretchable substrate, resulting in an upper plate including the stretchable substrate and a second electrode positioned on the stretchable substrate.

FIG. 7 is an optical microscope image illustrating an upper plate prepared according to Preparation Example 1.

### Example 1

### Preparation of Pressure Sensor

Polyethylene glycol diacrylate hydrogel (PEGDA hydrogel, Sigma Aldrich, Mw: 575) as a photocurable polymer, 1-butyl-3-methylimidazolium tetrafluoroborate (available from Sigma Aldrich) as a liquid electrolyte), and 2-hydroxy-2-methylpropiophenone (available from Sigma Aldrich) as a photoinitiator were mixed in a ratio of 40:58:2 (w/w) to prepare a mixture.

The mixture was applied on an aluminum electrode to form a first electrode/coating layer. A glass-type UV mask (pattern pitch: 1.25 mm) was placed on the first electrode/coating layer, and patterns are formed. After the UV irradiation, the mask was removed and the remaining mixture was washed with toluene, and heat treatment was performed at 80° C. for 30 minutes to remove the toluene. Thus, a lower plate including the first electrode and a pressure sensing unit positioned on the first electrode and including electrolyte patterns were prepared.

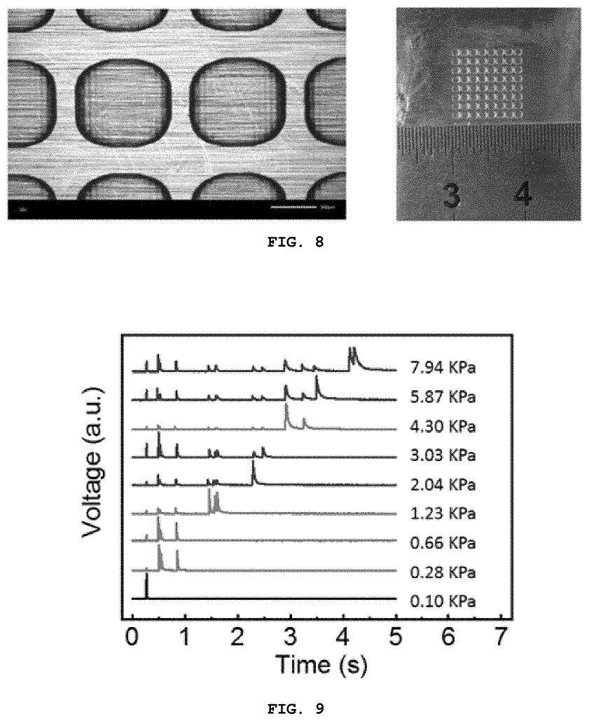

FIG. 8 includes an optical microscope image and an actual image of electrolyte patterns formed in a pressure sensor manufactured according to Example 1.

Spacers spaced apart from the pressure sensing unit of the lower plate and configured to partially or entirely surround the pressure sensing unit were formed between the first electrode of the lower plate and the second electrode of the upper plate manufactured according to Preparation Example 1, thereby providing a pressure sensor.

### Experimental Example

### Text Example 1

### Response of Pressure Sensor According to Pressure

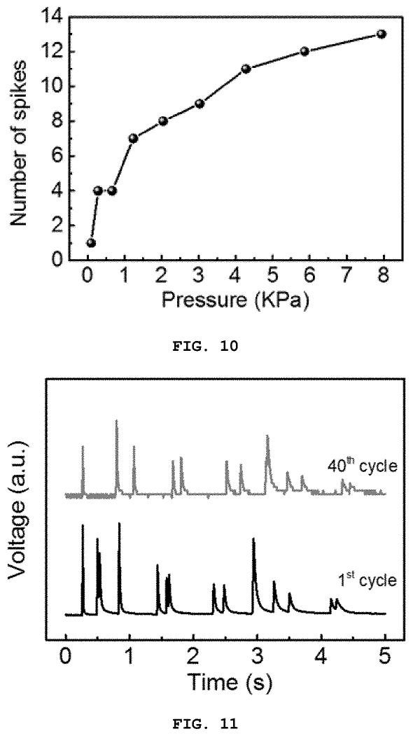

FIG. 9 shows a spike spectrum signal that is output according to the pressure applied to the pressure sensor manufactured according to Example 1, and FIG. 10 shows the number of spikes in the spike spectrum signal according to the pressure applied to the pressure sensor manufactured according to Example 1.

Referring to FIGS. 9 and 10, with pressure applied to the pressure sensor, a signal in the form of a spike spectrum can be obtained as pressure is applied. It is confirmed that the number of spikes in the spike spectrum increases as the pressure increases.

### Text Example 2

### Reproducibility of Pressure Sensor

FIG. 11 illustrates spike spectrum signals obtained when the same pressure is repeatedly applied to the pressure sensor manufactured according to Example 1.

Referring to FIG. 11, it is confirmed that there is no difference in the number of spikes in a single spike spectrum between the case where the same pressure is applied once and the case where the same pressure is applied 40 times. Therefore, it is confirmed that the pressure sensor manufactured according to Example 1 has reproducibility.

The scope of the present invention is defined by the following claims rather than the above detailed description, and all changes or modifications derived from the meaning and scope of the claims and their equivalent concepts should be interpreted as falling into the scope of the present invention.

### INDUSTRIAL APPLICABILITY

The pressure sensor of the present invention can provide reliable pressure sensing results even in an environment where noise may occur due to stable signal transmission of a spike spectrum, which is a kind of frequency-based signal.

1. A pressure sensor comprising:
a first electrode;
a pressure sensing unit positioned on the first electrode and including a pattern including an electrolyte;
a spacer positioned on the first electrode and configured to partially or entirely surround the pressure sensing unit; and
a second electrode positioned on the spacer and on the pressure sensing unit and spaced apart from the pressure sensing unit.

2. The pressure sensor according to claim 1, wherein the pressure sensor further comprises a stretchable substrate on the second electrode.

3. The pressure sensor according to claim 1, wherein the pattern comprises a plurality of domains, each of the domains comprises the electrolyte, and each of the domains is spaced apart from a neighboring domain of the plurality of domains.

4. The pressure sensor apparatus according to claim 3, wherein the domains have one or more shapes selected from the group consisting of linear, circular, elliptical, arc-shaped, sector-shaped, and polygonal shapes and combinations thereof.

5. The pressure sensor apparatus according to claim 3, wherein one domain of the plurality of domains has the same shape as a neighboring domain.

6. The pressure sensor according to claim 5, wherein one domain of the plurality of domains has the same size as a neighboring domain.

7. The pressure sensor according to claim 6, wherein the domains are arranged at regular intervals.

8. The pressure sensor apparatus according to claim 1, wherein the electrolyte comprises a photocurable polymer and a liquid electrolyte.

9. The pressure sensor apparatus according to claim 8, wherein the photocurable polymer comprises at least one selected from the group consisting of a diacrylate-based polymer and a dimethacrylate-based polymer.

10. The pressure sensor apparatus according to claim 8, wherein the electrolyte comprises an ionic liquid.

11. The pressure sensor according to claim 8, wherein the electrolyte further comprises a photoinitiator.

12. The pressure sensor according to claim 1, wherein the first electrode or the second electrode comprises at least one selected from the group consisting of gold, silver, copper, platinum, palladium, nickel, indium, aluminum, iron, rhodium, ruthenium, osmium, cobalt, molybdenum, zinc, vanadium, tungsten, titanium, manganese, chromium, silver nanowire, carbon nanotube (CNT), and gold nanosheet.

13. The pressure sensor according to claim 1, wherein the second electrode comprises a buckled structure.

14. The pressure sensor according to claim 13, wherein the buckle structure comprises a curved surface of the second electrode.

15. The pressure sensor according to claim 13, wherein the second electrode has a sectional surface having a zigzag shape including crests and valleys, the sectional surface being perpendicular to a plane direction of the second electrode.

16. The pressure sensor apparatus according to claim 2, wherein the stretchable substrate comprises at least one selected from the group consisting of a styrene-butadiene-styrene (SBS) block copolymer, a styrene-ethylene-butylene-styrene (SEBS) block copolymer, a styrene-isoprene-styrene (SIS) block copolymer, polyurethane (PU), polyisoprene rubber (IR), butadiene rubber (BR), ethylene-propylene-diene monomer (EPDM) rubber, polydimethylsiloxane (PDMS), silicone rubber, ecoflex and dragon skin.

17. A method of manufacturing a pressure sensor, the method comprising: (a) preparing a lower plate including a first electrode and a pressure sensing unit positioned on the first electrode and having a pattern including an electrolyte; (b) preparing an upper plate including a stretchable substrate and a second electrode positioned on the stretchable substrate; and (c) forming a spacer between the first electrode of the lower plate and the second electrode of the upper plate, the space being spaced apart from the pressure sensing unit and partially or entirely surrounding the pressure sensing unit.

18. The method according to claim 17, wherein the step (a) comprises: (a-1) preparing a mixture comprising a photocurable polymer precursor and a liquid electrolyte; (a-2) applying the mixture on the first electrode to prepare a first electrode/coating layer; (a-3) stacking a mask on the first electrode/coating layer to cover an upper surface of the first electrode/coating layer except for a portion to be patterned; (a-4) causing a structure resulting from the step (a-3) to be exposed to UV radiation; and (a-5) removing the mask to prepare a lower plate, and wherein the photocurable polymer precursor comprises at least one selected from the group consisting of photocurable monomers and photocurable oligomers.

19. The method according to claim 17, wherein the step (b) comprises: (b-1) pulling the stretchable substrate biaxial directions and fixing the stretchable substrate; (b-2) depositing a metal on the fixed stretchable substrate to form a metal layer on the stretchable substrate; and (b-3) releasing the fixed stretchable substrate to prepare an upper plate including the metal layer including a buckle structure formed on a surface thereof.
